(19) United States
(12) Patent Application Publication
(10) Pub. No.: US 2004/0106255 A1
(43) Pub. Date: Jun. 3, 2004

(54) Manufacturing method of flash memory device

(75) Inventor: Noriyuki Mitsuhira, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/448,352

(22) Filed: May 30, 2003

(30) Foreign Application Priority Data
Nov. 29, 2002 (JP) 2002-347058

(51) Int. Cl. H01L 21/336

(52) U.S. Cl. 438/257; 438/258

(57) ABSTRACT

A rewriting endurance of a flash memory is made to improve.

A first interlayer insulating film (10) is formed on a flash memory cell which is formed in a memory element region on a semiconductor substrate (100). At this time, a furnace anneal is added as a heat treatment after a NSG layer (16) which is a top layer of the first interlayer insulating film (10) is formed, instead of a heat treatment in a short time by means of a lamp anneal. According to it, a stress which is impressed on the flash memory cell is relaxed, and a rewriting endurance is improved. Moreover, the furnace anneal is added after a first and a second aluminum wirings (21 and 31) are formed. Furthermore, when a second and a third interlayer insulating films (20 and 30) are formed, a deposition temperature of plasma TEOS layers (23 and 33) is set to be identical with a temperature of HDP layers (22 and 32) at that time. According to it, in the same manner, the rewriting endurance of the flash memory cell is improved.

### BACKGROUND OF THE INVENTION

1. Field of the Invention

The present invention relates to a nonvolatile memory semiconductor device, and more particularly, it relates to a manufacturing method of a flash memory device.

2. Description of the Background Art

According to a miniaturization of a semiconductor device, a heat treatment time in a manufacturing process of the semiconductor device tends to become short for the purpose of suppressing a diffusion of an impurity which determines an electrical characteristic of a semiconductor element. Therefore, generally, a lamp anneal which enables a heat treatment in a short time is used for that heat treatment.

In the meantime, a furnace anneal (FA) is known as a heat treatment which needs comparatively a long time (a furnace anneal for electrodes is often called “sinter”.) In the lamp anneal, a heating is performed in a short time by means of irradiating an emitted light directly on an object for heating, and in the furnace anneal, on the other hand, a heating of comparatively slow is performed by means of exposing an object for heating in a predetermined temperature atmosphere.

Also in manufacturing a flash memory device which is a nonvolatile memory semiconductor device, with no exception to a tendency described above, the lamp anneal is used for a heat treatment of an interlayer insulating film and so on, for example.

There is also a technique to plan suppressing differences between various characteristics of flash memory cells and improving a data holding characteristic by means of performing a heat treatment by the furnace anneal as a heat treatment to floating gate electrodes which the flash memory cells have (for example, Japanese Patent Application Laid-Open No. 13-127178 (2001), (see page 3 and FIG. 1))

“Rewritable number” is a significant factor to determine a capacity of the flash memory device. To improve the rewritable number, that is to say, to improve a rewriting endurance is a significant problem in the flash memory device.

### SUMMARY OF THE INVENTION

It is an object of the present invention to provide a manufacturing method which enables improving a rewriting endurance of a flash memory device.

According to the first aspect of the present invention, a manufacturing method of a flash memory device includes the following steps (a) and (b). The step (a) is a step forming a flash memory cell on a semiconductor substrate. The step (b) is a step forming a first interlayer insulating film on the flash memory cell. Moreover, in the step (b), a furnace anneal is performed at least once or more as a heat treatment.

A stress which is put on the flash memory cell can be suppressed, and thus an effect can be obtained that the rewriting endurance of the flash memory device is improved.

According to the second aspect of the present invention, a manufacturing method of a flash memory device includes the following steps (a) to (c). The step (a) is a step forming a flash memory cell on a semiconductor substrate. The step (b) is a step forming a wiring which includes a metal on the flash memory cell. The step (c) is a step forming a second interlayer insulating film on the wiring. Moreover, in the step (c), a furnace anneal is performed at least once or more as a heat treatment.

The stress which is put on the flash memory cell can be suppressed, and thus an effect can be obtained that the rewriting endurance of the flash memory device is improved.

According to the third aspect of the present invention, a manufacturing method of a flash memory device includes the following steps (a) to (c). The step (a) is a step forming a flash memory cell on a semiconductor substrate. The step (b) is a step forming a wiring which includes a metal on the flash memory cell. The step (c) is a step forming a second interlayer insulating film of a multilayer structure on the wiring. Moreover, in the step (c), a deposition temperature of each layer of the multilayer structure is the same.

The stress which is put on the flash memory cell can be suppressed, and thus an effect can be obtained that the rewriting endurance of the flash memory device is improved.

According to the fourth aspect of the present invention, a manufacturing method of a flash memory device includes the following steps (a) to (c). The step (a) is a step forming a flash memory cell on a semiconductor substrate. The step (b) is a step forming a wiring which includes a metal on the flash memory cell, and performing a furnace anneal. The step (c) is a step forming a second interlayer insulating film on the wiring.

The stress which is put on the flash memory cell can be suppressed, and thus an effect can be obtained that the rewriting endurance of the flash memory device is improved.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 and 2 are drawings for describing a manufacturing method of a flash memory device according to the present invention.

FIGS. 3A and 3B are drawings for describing an effect of a manufacturing method of a flash memory according to a preferred embodiment 1.

FIG. 4 is a drawing illustrating a relationship between a condition of a furnace anneal which is performed when a first interlayer insulating film is formed and ΔVth with regard to the manufacturing method of the flash memory according to the preferred embodiment 1.

FIGS. 5A and 5B are drawings for describing an effect of a manufacturing method of a flash memory according to a preferred embodiment 2.

FIGS. 6A and 6B are drawings for describing an effect of a manufacturing method of a flash memory according to a preferred embodiment 3.

FIG. 7 is a graph illustrating changes of an erasing time corresponding with a rewriting number with regard to a flash memory device according to a preferred embodiment 4.

### DESCRIPTION OF THE PREFERRED EMBODIMENTS

<Preferred Embodiment 1>

As described above, with regard to the general manufacturing process of the semiconductor device which has a miniaturized structure, the heat treatment in a short time by means of the lamp anneal is valid. Therefore, the lamp anneal is also used in a manufacturing process of the device which has the flash memory (the flash memory device) as a matter of course.

The present inventor finds out that with regard to the manufacturing process of the flash memory device, in case of using the furnace anneal as the heat treatment of a predetermined interlayer insulating film, the rewritable number is improved as compared with the case that only the lamp anneal is used.

Generally, an atmospheric pressure CVD (Chemical Vapor Deposition) is used for a formation of an interlayer insulating film which covers a flash memory cell, and its deposition temperature is 300 to 400° C. When the lamp anneal is performed as the heat treatment of such an interlayer insulating film, the temperature of that interlayer insulating film rises suddenly, and thus, it tends to shrink rapidly. Moreover, it is considered that a stress caused by that shrinkage puts on the flash memory cell and lowers the rewriting endurance of the flash memory device.

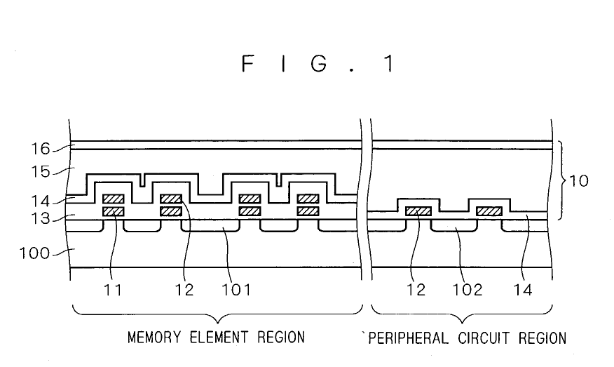

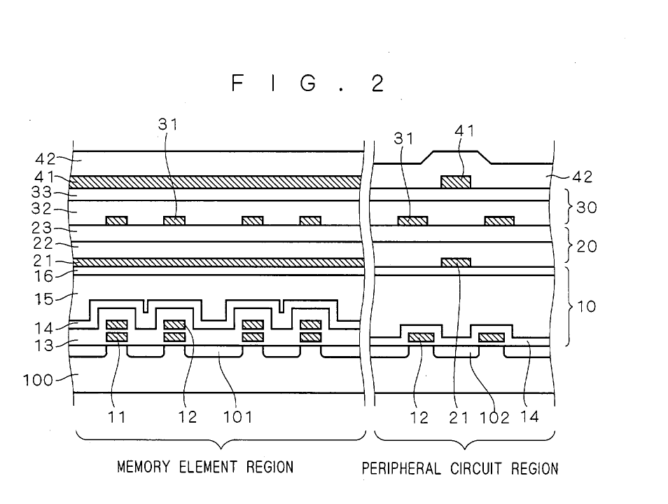

FIGS. 1 and 2 are drawings for describing a manufacturing method of a flash memory device according to the present invention and a cross sectional view when a first interlayer insulating layer which covers a flash memory cell is formed. In FIGS. 1 and 2, a memory element region which includes the flash memory cell is illustrated in a left side, and a peripheral circuit region is illustrated in a right side.

A manufactured method of the flash memory device according to the preferred embodiment 1 is described based on FIG. 1 and FIG. 2. First, in a common procedure, the flash memory cell which includes a floating gate 11, a control gate 12 and a source drain region 101 is formed in the memory element region on a semiconductor substrate 100 and a transistor which includes the control gate 12 and a source drain region 102 is formed in the peripheral circuit region on the semiconductor substrate 100.

Afterwards, a first interlayer insulating film 10 which is composed of a multilayer structure of a TEOS (tetraethyl orthosilicate) layer 13, a NSG (non-doped silicate glass) layer 14, a BPTEOS (boro-phospho tetraethylorthosilicate) layer 15 and a NSG layer 16 is formed on the flash memory cell. First, as its lowest layer, the TEOS layer 13 to form a cobalt silicide (CoSi) selectively on the mere transistor of the peripheral circuit region (described as “a SP-TEOS layer (a silicide protection TEOS layer)” hereinafter) is formed by means of a low pressure CVD on the flash memory cell. Moreover, after forming the cobalt silicide on the transistor of the peripheral circuit region, the NSG layer 14 to prevent an impurity which is doped on the BPTEOS layer 15 of the upper layer from entering an active layer of that transistor is formed by means of the atmospheric pressure CVD. Next, the BPTEOS layer 15 is deposited by means of the atmospheric pressure CVD, and for a sintering, the lamp anneal of 800° C. is added for thirty seconds.

Next, an upper surface of the BPTEO layer 15 is flatted by means of a CMP (Chemical Mechanical Polishing), and the NSG layer 16 is deposited by means of the atmospheric pressure CVD as a topmost layer of a first interlayer insulating film 10. Here, after forming the NSG layer 16, the heat treatment is performed for the sintering. Conventionally, the lamp anneal of 800° C. is performed for thirty seconds as this heat treatment, however, in the present preferred embodiment, the furnace anneal of 800° C. is added for thirty minutes instead. As an atmosphere of this furnace anneal, for example, a hydrogen atmosphere, a nitrogen atmosphere, an argon atmosphere and so on are mentioned, and any of them can be applied.

Afterwards, after a contact (non-illustrated) is formed on the interlayer insulating film 10, as shown in FIG. 2, a first aluminum wiring 21 is formed, and a second interlayer insulating film 20 which is composed of a double layer structure of a HDP layer 22 and a plasma TEOS layer 23 is formed on it. And moreover, after a contact (non-illustrated) is formed on the second interlayer insulating film 20, a second aluminum wiring 31 is formed, and a third interlayer insulating film 30 which is composed of a double-layer structure of a HDP layer 32 and a plasma TEOS layer 33 is formed on it. And, after a contact (non-illustrated) is formed on the third interlayer insulating film 30, a third aluminum wiring 41 which is a topmost wiring is formed, and finally, a surface of the device is covered with a glass coat 42.

Here, the flash memory device which has a wiring structure of triple layers above the flash memory cell is described as an example, however, an application of the present invention is not limited to it. For example, it is clear that this is also applicable to any flash memory device which has a wiring structure of a single layer or a wiring structure of double layers or more.

The furnace anneal is performed at the timing after the NSG layer 16 in the first interlayer insulating film 10 is formed in the above description, however, the timing when the furnace anneal is performed is not limited to this in the present invention. For example, the furnace anneal can be performed as the heat treatment right after the BPTEOS layer 15 is deposited.

The furnace anneal can be performed as both the heat treatment right after the BPTEOS layer 15 is deposited and the heat treatment after the NSG layer 16 is formed. However, by reason that the furnace anneal needs comparatively a long time for the treatment, a manufacturing efficiency may sharply be deteriorated when the performance of the furnace anneal increases in number.

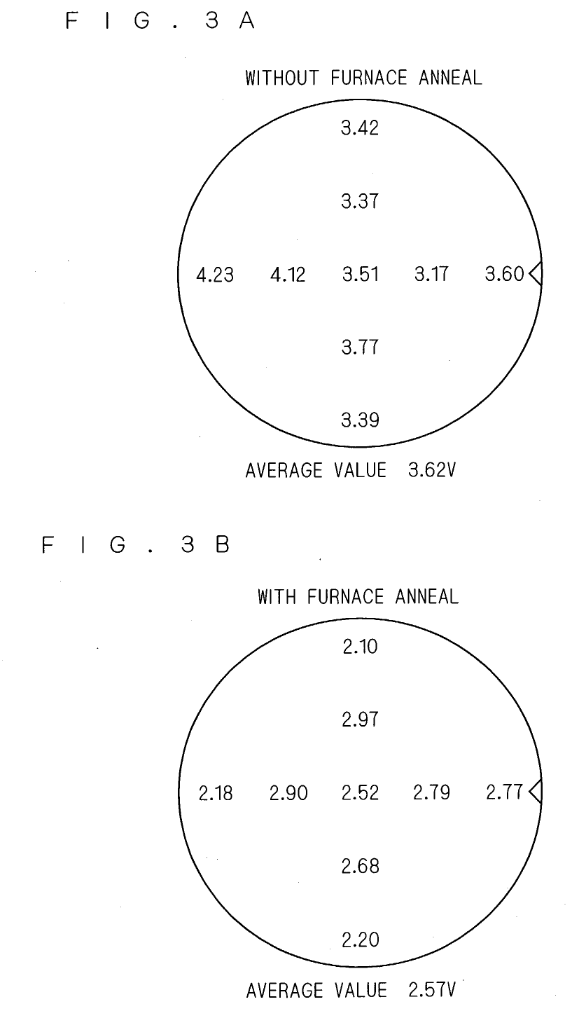

FIGS. 3A and 3B are drawings for describing an effect of the preferred embodiment 1 and distribution charts of a fluctuation amount ΔVth of a gate threshold voltage on a wafer when a predetermined stress is put on a floating electrode transistor of the flash memory cell. It can be assumed that the smaller the value of ΔVth is, the higher the rewriting endurance of this memory cell is. FIG. 3A is a distribution chart on a wafer in which the flash memory device which has the first interlayer insulating film 10 which is formed by means of a conventional manufacturing method (that is to say, only the lamp anneal is used for the sintering when each layer is formed) is formed. FIG. 3B is a distribution chart on a wafer in which the flash memory device which has the first interlayer insulating film 10 which is formed by means of the manufacturing method according to the preferred embodiment 1 is formed.

Each flash memory device of FIG. 3A and FIG. 3B is formed under the identical condition with each other except for the forming process of the first interlayer insulating film 10. Moreover, FIG. 3A and FIG. 3B are both based on the data which is obtained from the wafer in the identical lot.

As shown in FIGS. 3A and 3B, with regard to the flash memory device according to the present preferred embodiment, it can be confirmed that ΔVth is improved about 1.0 V or so as compared with the conventional flash memory device. That is to say, according to the manufacturing method of the flash memory according to the present preferred embodiment, the improvement of the rewriting endurance of the memory cell can be obtained.

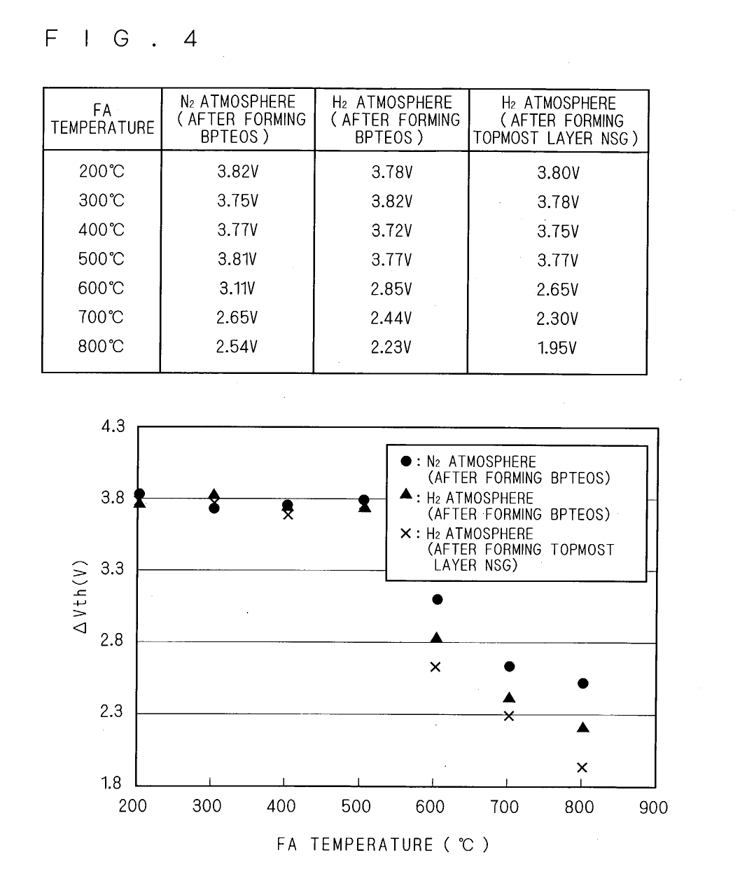

FIG. 4 is a drawing illustrating changes of ΔVth in case that each of a temperature, an atmosphere and a timing of the furnace anneal which is performed when the first interlayer insulating film 10 is formed is changed. From FIG. 4, the below description can be recognized. That is to say, (1) is: when the temperature of the furnace anneal becomes 600° C. or more, the effect to suppress ΔVth is especially improved. (2) is: the furnace anneal in the hydrogen atmosphere has more effect to suppress ΔVth than the furnace anneal in the nitrogen atmosphere. (3) is: with regard to the timing to perform the furnace anneal, the performance has more effect to suppress ΔVth when it is performed after the NSG layer 16 which is the top layer of the first interlayer insulating film 10 is formed than the performance which is performed right after the BPTEOS layer 15 is formed. Moreover, although the illustration is omitted, however, the effect to suppress ΔVth can also be obtained by means of the furnace anneal in the argon atmosphere. However, the effect to be obtained is less than that in the hydrogen atmosphere.

That is to say, the improvement of the rewriting endurance of the flash memory device can be obtained more effectively by means of setting the temperature of the furnace anneal to be 600° C. or more when the first interlayer insulating film 10 is formed, the atmosphere of that furnace anneal to be the hydrogen atmosphere and the timing to perform that anneal to be after the NSG layer 16 which is the top layer of the first interlayer insulating film 10 is formed.

The above description is based on the assumption that the temperature of the furnace anneal which is performed when the first interlayer insulating film 10 is formed is to be 800° C., the same as the temperature of the lamp anneal in the conventional manufacturing method, however, in case of the furnace anneal, by reason that the heat treatment time becomes longer than the case of the lamp anneal, it may affect the transistor (for example, a short channel effect and so on). In that case, it is desirable to lower the temperature of that furnace anneal. However, when the temperature is lowered, it is expected that the problem may occur that an activation rate of an impurity in the source drain region and so on of the transistor lowers. It is expected that the problem can be solved by means of performing the lamp anneal whose temperature is 800° C. or more after the contact is formed, the impurity is injected and so on.

<Preferred Embodiment 2>

In the present preferred embodiment, a forming process of a wiring which is formed above a flash memory cell and an interlayer insulating film which covers the wiring according to the present invention is described.

The interlayer insulating film which covers the wiring which is formed above the flash memory cell is formed by means of depositing a HDP (high density plasma) film which is superior in a coverage characteristic right on the wiring, depositing a plasma TEOS film on it and flat it. Generally, the deposition temperature of the HDP film is 300° C. or so, and the deposition temperature of the plasma TEOS film is 400° C. The present inventor considers that by reason that each deposition temperature is different from the other, during the deposition of the plasma TEOS film, the temperature of the HDP film rises suddenly, and the HDP film tends to shrink rapidly, therefore, the stress caused by that shrinkage puts on the lower flash memory cell and lowers the rewriting endurance.

A manufacturing process of the flash memory device according to the present preferred embodiment is described. First, by the same step as the preferred embodiment 1, as shown in FIG. 1, the flash memory cell is formed in the memory element region on the semiconductor substrate 100, the transistor is formed in the peripheral circuit region on the semiconductor substrate 100 and the first interlayer insulating film 10 is formed on them.

Afterwards, after a contact (non-illustrated) is formed on the first interlayer insulating film 10, as shown in FIG. 2, a first aluminum wiring 21 is formed, and a HDP layer 22 is deposited on it at the deposition temperature of 300° C. In the present preferred embodiment, the furnace anneal of 400° C. is added for fifteen minutes at this time. Any of the hydrogen atmosphere, the nitrogen atmosphere, the argon atmosphere and so on, for example, can be the atmosphere of this furnace anneal. As a result, the temperature of the HDP layer 22 (wafer temperature) becomes 400° C. Moreover, the plasma TEOS layer 23 is made to deposit on that HDP layer 22 at the deposition temperature of 400° C., the same as the temperature of the furnace anneal described above. That is to say, at this time, the deposition temperature of the plasma TEOS layer 23 is the same as the temperature of the HDP layer 22. Moreover, the upper surface of the plasma TEOS layer 23 is flatted by means of the CMP, and the formation of the second interlayer insulating film 20 is completed.

According to the present preferred embodiment, the deposition temperature of the plasma TEOS layer 23 becomes identical with the temperature of the HDP layer 22 at that time by means of adding the furnace anneal of the identical temperature with the deposition temperature of the plasma TEOS layer 23 which is deposited after the HDP layer 22 is formed. Accordingly, during the deposition of the plasma TEOS layer 23, the HDP layer 22 does not shrink rapidly, thus the stress which is put on the lower flash memory cell is suppressed.

After a contact (non-illustrated) is formed on the second interlayer insulating film 20, the second aluminum wiring 31 is formed, and the third interlayer insulating film 30 is formed on it by means of the same method as the second interlayer insulating film 20 described above. That is to say, the HDP layer 32 is deposited at the temperature of 300° C. on the second aluminum wiring 31, and the furnace anneal of 400° C. is added for fifteen minutes. Next, the plasma TEOS layer 33 is made to deposit on it at the deposition temperature of 400° C., the upper surface of it is flatted by means of the CMP and the third interlayer insulating film 30 is formed. Also in this case, during the deposition of the plasma TEOS layer 33, the HDP layer 32 does not shrink rapidly, thus the stress which is put on the lower flash memory cell is suppressed.

Thereafter, in the same manner as the preferred embodiment 1, after the contact (non-illustrated) is formed above the third interlayer insulating film 30, the third aluminum wiring 41 which is the topmost wiring is formed, and finally, the surface of the device is covered with the glass coat 42.

Also in the present preferred embodiment, the flash memory device which has the wiring structure of triple layers on the flash memory cell is described as the example, however, it is clear that this is also applicable to any flash memory device which has the wiring structure of the double layers or more.

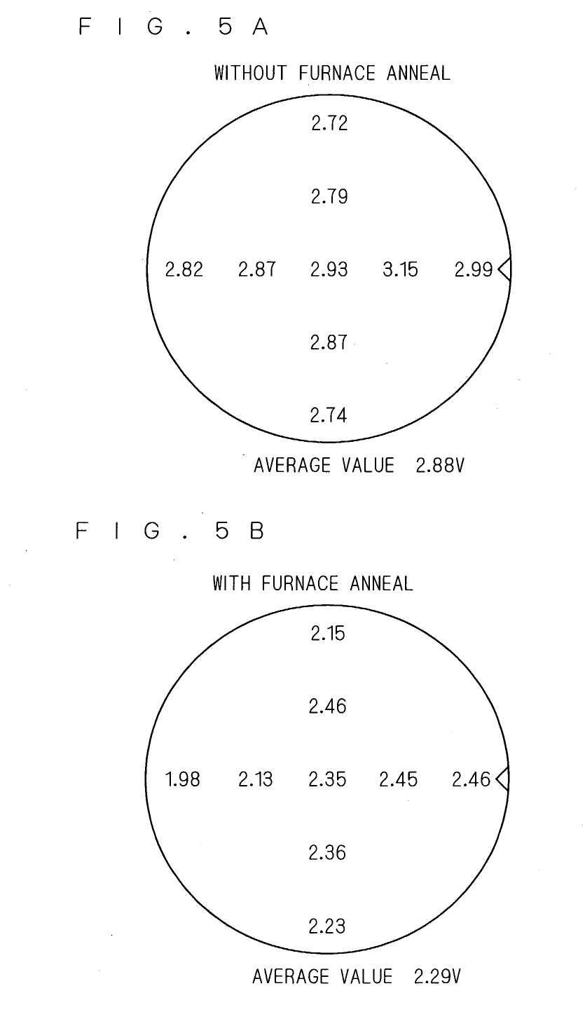

FIGS. 5A and 5B are drawings for describing an effect of the preferred embodiment 2 and distribution charts of a fluctuation amount ΔVth of a gate threshold voltage on a wafer when a stress is put on a floating electrode transistor of the flash memory cell. FIG. 5A is the distribution chart on the wafer where the flash memory device which has the second and the third interlayer insulating films 20 and 30 which are formed by means of the conventional manufacturing process (that is to say, the HDP layers 22 and 32 are deposited at the deposition temperature of 300° C., and the plasma TEOS layers 23 and 33 are deposited at the deposition temperature of 400° C. without adding the furnace anneal) is formed. FIG. 5B is the distribution chart on the wafer where the flash memory device which has the second and the third interlayer insulating films 20 and 30 which are formed by means of the manufacturing process according to the preferred embodiment 2 is formed.

Each flash memory device of FIG. 5A and FIG. 5B is formed under the identical condition with each other except for the forming process of the second interlayer insulating film 10, and the first interlayer insulating film 10 which both the flash memory devices have is formed by means of the forming process of the preferred embodiment 1. Moreover, FIG. 5A and FIG. 5B are both based on the data which is obtained from the wafer in the identical lot.

As shown in FIGS. 5A and 5B, with regard to the flash memory device according to the present preferred embodiment, it can be confirmed that ΔVth is improved about 0.6 V or so as compared with the conventional flash memory device. That is to say, according to the manufacturing method of the flash memory according to the present preferred embodiment, the improvement of the rewriting endurance of the memory cell can be obtained.

As described above, any of the hydrogen atmosphere, the nitrogen atmosphere, the argon atmosphere and so on, for example, can be the atmosphere of the furnace anneal which is added to the HDP layer 22, however, it is confirmed by the present inventor that in case that the furnace anneal of the hydrogen atmosphere is performed among the rest, the improvement of the rewriting endurance of the flash memory device can be obtained more effectively.

<Preferred Embodiment 3>

A manufacturing process of the flash memory device according to the preferred embodiment 3 is described. First by the same step as the preferred embodiment 1, as shown in FIG. 1, the flash memory cell is formed in the memory element region on the semiconductor substrate 100, the transistor is formed in the peripheral circuit region on the semiconductor substrate 100 and the first interlayer insulating film 10 is formed on them.

Afterwards, after a contact (non-illustrated) is formed on the interlayer insulating film 10, as shown in FIG. 2, a first aluminum wiring 21 is formed, and the HDP layer 22 is deposited at the deposition temperature of 400° C. on it. Moreover, the plasma TEOS layer 23 is made to deposit on that HDP layer 22 at the deposition temperature of 400° C., the same as the deposition temperature of the HDP layer 22 described above. That is to say, at this time, the deposition temperature of the plasma TEOS layer 23 is the same as the temperature of the HDP layer 22 (wafer temperature). Moreover, the upper surface of the plasma TEOS layer 23 is flatted by means of the CMP, and the formation of the second interlayer insulating film 20 is completed.

According to the present preferred embodiment, the deposition temperature of the HDP layer 22 is set to be the same as the deposition temperature of the plasma TEOS layer 23 which is deposited afterwards, therefore, during the deposition of the plasma TEOS layer 23, the HDP layer 22 does not shrink rapidly, thus the stress which is put on the lower flash memory cell is suppressed.

After a contact (non-illustrated) is formed on the second interlayer insulating film 20, the second aluminum wiring 31 is formed, and the third interlayer insulating film 30 is formed on it by means of the same method as the second interlayer insulating film 20 described above. That is to say, both the HDP layer 32 and the plasma TEOS layer 33 are deposited at the temperature of 400° C., the upper surface of the plasma TEOS layer 33 is flatted by means of the CMP, and the third interlayer insulating film 30 is formed. As a result, during the deposition of the plasma TEOS layer 33, the HDP layer 32 does not shrink rapidly, thus the stress which is put on the lower flash memory cell is suppressed.

Thereafter, in the same manner as the preferred embodiment 1, after the contact (non-illustrated) is formed on the third interlayer insulating film 30, the third aluminum wiring 41 which is the topmost wiring is formed, and finally, the surface of the device is covered with the glass coat 42.

Also in the present preferred embodiment, the flash memory device which has the wiring structure of triple layers above the flash memory cell is described as the example, however, it is clear that this is also applicable to any flash memory device which has the wiring structure of the double layers or more.

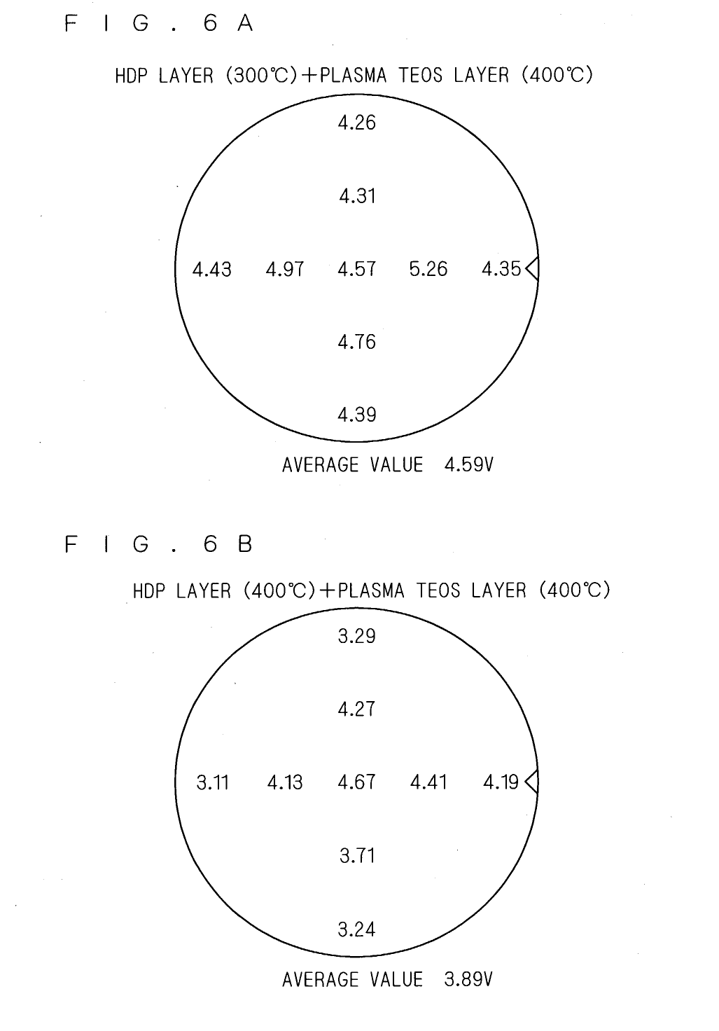

FIG. 6A and FIG. 6B are drawings for describing an effect of the preferred embodiment 3 and distribution charts of a fluctuation amount ΔVth of a gate threshold voltage on a wafer when a stress is put on a floating electrode transistor of the flash memory cell. FIG. 6A is the distribution chart on the wafer where the flash memory device which has the second and the third interlayer insulating films 20 and 30 which are formed by means of the conventional manufacturing process (that is to say, the HDP layers 22 and 32 are deposited at the deposition temperature of 300° C., and the plasma TEOS layers 23 and 33 are deposited at the deposition temperature of 400° C., respectively) is formed. FIG. 6B is the distribution chart on the wafer where the flash memory device which has the second and the third interlayer insulating films 20 and 30 which are formed by means of the manufacturing process according to the preferred embodiment 3 is formed.

Each flash memory device of FIG. 6A and FIG. 6B is formed under the identical condition with each other except for the forming process of the second interlayer insulating film 10, and the first interlayer insulating film 10 which both the flash memory devices have is formed by means of the conventional forming process (only the lamp anneal is used for the heat treatment of each layer). Moreover, FIG. 6A and FIG. 6B are both based on the data which is obtained from the wafer in the identical lot.

As shown in FIGS. 5A and 5B, with regard to the flash memory device according to the present preferred embodiment, it can be confirmed that ΔVth is improved about 0.7 V or so as compared with the conventional flash memory device. That is to say, according to the manufacturing method of the flash memory according to the present preferred embodiment, the improvement of the rewriting endurance of the memory cell can be obtained.

In the above description described above, both the HDP layers 22 and 32, and both the plasma TEOS layers 23 and 33 are formed setting the deposition temperature to be 400° C., however, both of them can be set to be 300° C., and the effect similar to the above description can be obtained.

In the present preferred embodiment, the second interlayer insulating film 20 and the third interlayer insulating film 30 which respectively have the double layer structure are described as an example, however, an application of the present invention is not limited to it, and they can also have the multilayer structure of the triple layers or more. In that case, by means that all of the layers of that multilayer structure are formed at the same deposition temperature, the stress which is generated when each layer is formed can be suppressed.

<Preferred Embodiment 4>

The present inventor finds out that the rewriting endurance of the flash memory cell is improved by means of adding the furnace anneal on the wiring which is formed above that flash memory cell after being formed, also. It is assumed that it is because the stress which is generated when the wiring is formed impresses on the flash memory cell through the interlayer insulating film, and the stress is relaxed by that furnace anneal after the wiring is formed.

A manufacturing process of the flash memory device according to the preferred embodiment 4 is described. First, by the same step as the preferred embodiment 1, as shown in FIG. 1, the flash memory cell is formed in the memory element region on the semiconductor substrate 100, the transistor is formed in the peripheral circuit region on the semiconductor substrate 100 and the first interlayer insulating film 10 is formed on them.

Afterwards, after a contact (non-illustrated) is formed on the first interlayer insulating film 10, as shown in FIG. 2, a first aluminum wiring 21 is formed. In the present preferred embodiment, the furnace anneal of 400° C. is performed for fifteen minutes at this time. Any of the hydrogen atmosphere, the nitrogen atmosphere, the argon atmosphere and so on, for example, can be the atmosphere of this furnace anneal. Moreover, by means that the HDP layer 22 and the plasma TEOS layer 23 are made to deposit on it at the predetermined deposition temperature and the upper surface is flatted by means of the CMP, the formation of the second interlayer insulating film 20 is formed.

After a contact (non-illustrated) is formed on the second interlayer insulating film 20, the second aluminum wiring 31 is formed, and at this time, in the same manner as the case described above when the first aluminum wiring 21 is formed, the furnace anneal of 400° C. is added for fifteen minutes. Moreover, by means that the HDP layer 32 and the plasma TEOS layer 33 are made to deposit on it at the predetermined deposition temperature and the upper surface is flatted by means of the CMP, the formation of the third interlayer insulating film 30 is formed.

Thereafter, in the same manner as the preferred embodiment 1, after the contact (non-illustrated) is formed on the third interlayer insulating film 30, the third aluminum wiring 41 which is the topmost wiring is formed, and finally, the surface of the device is covered with the glass coat 42.

By means of performing the furnace anneal when the first aluminum wiring 21 and the second aluminum wiring 31 above the flash memory cell are formed as the present preferred embodiment, the rewriting endurance of the flash memory device is improved.

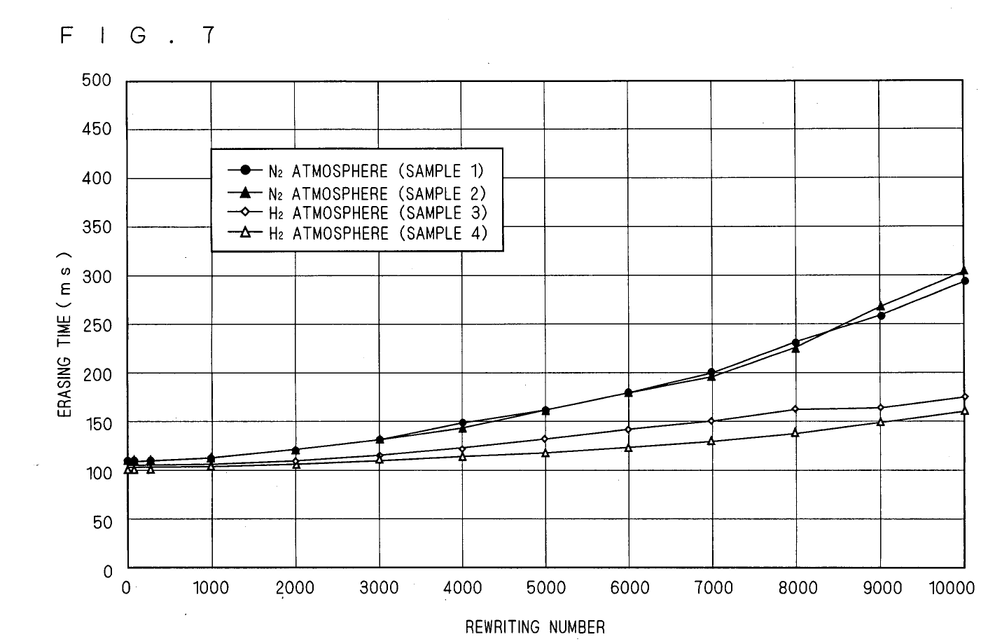

FIG. 7 is a graph illustrating changes of an erasing time corresponding with a rewriting number (write/erase number) with regard to a flash memory device according to the present preferred embodiment. In FIG. 7, the comparison between a case that the furnace anneal which is added after the first aluminum wiring 21 and the second aluminum wiring 31 are formed is performed in the nitrogen atmosphere (samples 1 and 2) and a case that the furnace anneal which is added after the first aluminum wiring 21 and the second aluminum wiring 31 are formed is performed in the hydrogen atmosphere (samples 3 and 4) is described. As can be seen from FIG. 7, in case of performing that furnace anneal in the hydrogen atmosphere, the deterioration of the erasing time after rewriting many times is suppressed by comparison with the case of performing that furnace anneal in the nitrogen atmosphere. That is to say, in the present embodiment, by means of performing the furnace anneal after the first aluminum wiring 21 and the second aluminum wiring 31 are formed in the hydrogen atmosphere, the improvement of the rewriting endurance of the flash memory device can be obtained more effectively.

In the description described above, the description of the deposition temperature of the HDP layers 22 and 32, and the plasma TEOS layers 23 and 33 is omitted, however, it is desirable to form them setting the deposition temperature to be 400° C., similar to the temperature of the furnace anneal after the wirings 21 and 31 are formed. As is evident from the preferred embodiment 3 described above, the stress which is generated when the second interlayer insulating film 20 and the third interlayer insulating film 30 are formed is suppressed, thus the effect of the improvement in the rewriting endurance of the flash memory device can be obtained more.

In the preferred embodiments 2 to 4, it is described that the deposition temperature of each layer of the second interlayer insulating film 20 and the third interlayer insulating film 30 and the temperature of the furnace anneal are identical with each other. However, originally, deposition devices and furnace anneal devices have errors in the temperature, thus it is often difficult to accord completely the temperature with each other. However, the difference of the temperature in approximately 10% is within the permissible limit to obtain fully the effect of the present invention.

The aluminum wiring is described as the first wiring 21, the second wiring 31 and the third wiring 41, however, an application of the present invention is not limited to it. For example, they can be the wirings which includes the other metals such as cupper (Cu), tungsten (W) and so on, and they can also be the wirings which are formed of the mere pure metal.

While the invention has been shown and described in detail, the foregoing description is in all aspects illustrative and not restrictive. It is therefore understood that numerous modifications and variations can be devised without departing from the scope of the invention.

What is claimed is:

1. A manufacturing method of a flash memory device, comprising the steps of:
(a) forming a flash memory cell on a semiconductor substrate; and
(b) forming a first interlayer insulating film on said flash memory cell; wherein
in said step (b), a furnace anneal is performed at least once or more as a heat treatment.

2. The manufacturing method of the flash memory device according to claim 1, wherein
said first interlayer insulating film has a multilayer structure, and
in said step (b), said furnace anneal is performed after a top layer of said multilayer structure is formed.

3. The manufacturing method of the flash memory device according to claim 1, wherein
a temperature of said furnace anneal is 600° C. or more.

4. The manufacturing method of the flash memory device according to claim 1, wherein
said furnace anneal is performed in a hydrogen atmosphere.

5. A manufacturing method of a flash memory device, comprising the steps of:
(a) forming a flash memory cell on a semiconductor substrate;
(b) forming wiring which include a metal above said flash memory cell; and
(c) forming second interlayer insulating films on said wirings; wherein
in said step (c), a furnace anneal is performed at least once or more as a heat treatment.

6. The manufacturing method of the flash memory device according to claim 5, wherein
said second interlayer insulating films have a multilayer structure and
in said step (c), a temperature of said furnace anneal is the same as a deposition temperature of a layer which is formed after said furnace anneal is performed in said multilayer structure.

7. The manufacturing method of the flash memory device according to claim 5, wherein
said furnace anneal is performed in a hydrogen atmosphere.

8. A manufacturing method of a flash memory device, comprising the steps of:
(a) forming a flash memory cell on a semiconductor substrate;
(b) forming wirings which include a metal above said flash memory cell; and
(c) forming second interlayer insulating films of a multilayer structure on said wirings; wherein
in said step (c), a deposition temperature of each layer of said multilayer structure is the same.

9. A manufacturing method of a flash memory device, comprising the steps of:
(a) forming a flash memory cell on a semiconductor substrate;
(b) forming wirings which include a metal above said flash memory cell and performing a furnace anneal; and
(c) forming second interlayer insulating films on said wirings.

10. The manufacturing method of the flash memory device according to claim 9, wherein
a temperature of said furnace anneal is the same as a deposition temperature of said second interlayer insulating films.

11. The manufacturing method of the flash memory device according to claim 9, wherein
said furnace anneal is performed in a hydrogen atmosphere.
